(19) United States
(12) Patent Application Publication
(10) Pub. No.: US 2026/0236840 A1
(43) Pub. Date: Aug. 13, 2026

(54) METHOD AND DEVICE WITH VIRTUAL MEASUREMENT

(71) Applicant: Samsung Electronics Co., Ltd., Suwon-si (KR)

(72) Inventors: Junhyun NAM, Suwon-si (KR); Jongin LIM, Suwon-si (KR); Minsoo KANG, Suwon-si (KR); Minsu KO, Suwon-si (KR); Sungun PARK, Suwon-si (KR); Sungjoo SUH, Suwon-si (KR)

(73) Assignee: Samsung Electronics Co., Ltd., Suwon-si (KR)

(21) Appl. No.: 19/301,706

(22) Filed: Aug. 15, 2025

(30) Foreign Application Priority Data
Feb. 11, 2025 (KR) 10-2025-0017428

(51) Int. Cl. G06N 20/00

(52) U.S. Cl. CPC G06N 20/00

(57) ABSTRACT

Provided is a method of training a virtual measurement model of a substrate. The virtual measurement model includes a first model and a second model. The method includes identifying at least one piece of representative data determined based on a plurality of input data associated with a process of processing the substrate, training the first model, based on input data and the at least one piece of representative data, to extract and output a feature of the input data and a feature of the at least one piece of representative data, and training the second model, based on the feature of the input data and the feature of the at least one piece of representative data outputted from the first model, to generate virtual measurement data corresponding to the input data.

### CROSS-REFERENCE TO RELATED APPLICATIONS

This application claims the benefit under 35 USC § 119 (a) of Korean Patent Application No. 10-2025-0017428, filed on Feb. 11, 2025, in the Korean Intellectual Property Office, the disclosure of which is incorporated herein by reference in its entirety.

### BACKGROUND

### 1. Field

Example embodiments relate to a method and device with virtual measurement.

### 2. Description of Related Art

Various processes, such as etching and deposition, may be performed on a substrate during the manufacture of a semiconductor device. Generally, characteristics of a processed substrate are measured using physical measuring equipment to accurately monitor and control process outcomes. However, such physical measurement methods can be time-consuming and costly, potentially reducing overall productivity. Accordingly, there is a need for improved measurement techniques that enhance efficiency while maintaining precision.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a processor-implemented method include identifying at least one piece of representative data determined based on a plurality of input data associated with a process of processing a substrate; training the first model, based on the input data and the at least one piece of representative data, to extract and output a feature of the input data and a feature of the at least one piece of representative data; and training the second model, based on the features outputted from the first model, to generate virtual measurement data corresponding to the input data.

The identifying of the at least one piece of representative data may include classifying the plurality of input data into a plurality of groups based on a criterion related to the process; and identifying at least one piece of representative data determined for a group to which a criterion identical to a criterion of the input data is applied among the plurality of groups.

The criterion may include either one or both of equipment performing the process and a target value of the process.

The identifying of the at least one piece of representative data may include in response to a fixed processing time for a process corresponding to the input data, identifying the at least one piece of representative data based on an average or a medoid using Euclidean distance among the input data included in the group to which the identical criterion applied to the input data is applied.

The identifying of the at least one piece of representative data may include in response to a variable processing time for a process corresponding to the input data, identifying the at least one piece of representative data based on barycenter averaging using dynamic time warping among the input data included in the group to which the identical criterion applied to the input data is applied.

The training of the first model may include inputting the input data and the at least one piece of representative data, having the identical criterion, into the first model, to extract a feature of the input data and a feature of the at least one piece of representative data; and training the first model to decrease a value of a first loss function based on the feature of the input data and the feature of the at least one piece of representative data.

The first loss function may include a metric indicating a difference between the feature of the input data and the feature of the at least one piece of representative data; a hyperparameter indicating sharpness; and a similarity between first measurement data corresponding to the input data and second measurement data corresponding to the at least one piece of representative data.

The training of the second model may include extracting the feature of the input data and the feature of the at least one piece of representative data using the first model; generating the virtual measurement data using the second model based on the extracted features; and training the second model to decrease a value of a second loss function based on the generated virtual measurement data.

The second loss function may include the virtual measurement data and a difference between first measurement data corresponding to the input data and second measurement data corresponding to the at least one piece of representative data.

The plurality of input data may include one or more of: sensing data obtained by measuring the substrate during the process; condition data of the process; and monitoring data of equipment performing the process.

In one general aspect, a processor-implemented method of virtual measurement of a substrate includes obtaining input data associated with a process of processing the substrate; identifying at least one piece of representative data corresponding to the input data; and based on a comparison between the input data and the at least one piece of representative data, generating virtual measurement data for the substrate using a virtual measurement model.

The identifying of the at least one piece of representative data may include selecting, from among a plurality of representative data stored in a memory, the at least one piece of representative data having a criteria identical to a criterion of the input data.

The virtual measurement model may include a first model configured to extract a feature of the input data and a feature of the at least one piece of representative data; and a second model configured to generate virtual measurement data corresponding to the input data based on the extracted features outputted by the first model.

The first model may be trained to decrease a value of a first loss function based on the feature of the input data and the feature of the at least one piece of representative data.

The second model may be trained to generate the virtual measurement data and decrease a value of a second loss function including the virtual measurement data and a difference between first measurement data corresponding to the input data and second measurement data corresponding to the at least one piece of representative data.

The second model may generate the virtual measurement data for the substrate based on a final feature indicating a difference between the feature of the input data and the feature of the at least one piece of representative data is inputted, and wherein the final feature is determined using a metric corresponding to the difference.

In one general aspect, an electronic device includes a memory; a transceiver configured to receive input data related to a process of processing a substrate from processing equipment; a first processor configured to identify, from the memory, at least one piece of representative data having a criterion identical to that of the input data and to output the input data and the at least one piece of representative data; and a second processor configured to generatae virtual measurement data for the substrate based on a comparison between the input data and the at least one piece of representative data.

The virtual measurement data may be compared with a threshold range, and an alarm is triggered when the virtual measurement data falls outside the threshold range.

The memory may store a virtual measurement model trained to output the virtual measurement data based on the comparison between the input data and the at least one piece of representative data.

In one general aspect, a system for generating representative data for virtual measurement of a substrate includes one or more processors each comprising a processing circuit, and a memory comprising one or more storage media storing instructions. The instructions, when executed by the one or more processors individually or collectively, cause the system to classify a plurality of input data related to substrate processing into groups based on process criteria, wherein the process criteria comprises at least one of a processing equipment identifier or a process target value; generate representative data for each group by applying Euclidean distance-based medoid selection when processing times for the group are fixed, or applying dynamic time warping (DTW)-based barycenter averaging when processing times for the group are variable; and store, in the memory, the generated representative data classified according to the process criteria for retrieval during virtual measurement operations.

Other features and aspects will be apparent from the following detailed description, the drawings, and the claims.

### BRIEF DESCRIPTION OF THE DRAWINGS

FIG. 1 illustrates a virtual measurement system according to one or more embodiments.

FIG. 2 illustrates a virtual measurement system according to one or more embodiments.

FIG. 3 illustrates a method of training a virtual measurement model according to one or more embodiments.

FIG. 4 illustrates a method of training a virtual measurement model according to one or more embodiments.

FIG. 5 illustrates a relationship between input data and representative data according to one or more embodiments.

FIG. 6 illustrates a process of generating representative data by processing input data according to one or more embodiments.

FIG. 7 illustrates a method of training a virtual measurement model according to one or more embodiments.

FIG. 8 illustrates a virtual measurement system according to one or more embodiments.

FIG. 9 illustrates a method of virtual measurement of a substrate according to one or more embodiments.

FIG. 10 illustrates an electronic device according to one or more embodiments.

Throughout the drawings and the detailed description, unless otherwise described or provided, the same or like drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

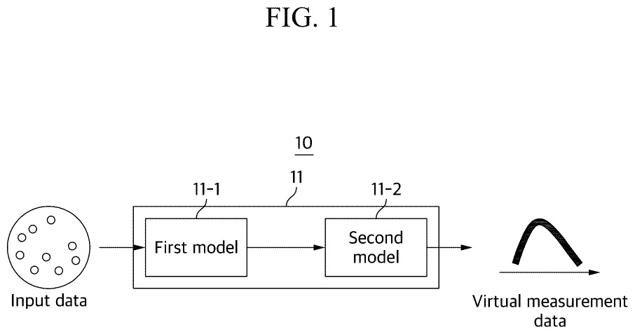

FIG. 1 illustrates a virtual measurement system according to one or more embodiments.

Referring to FIG. 1, a virtual measurement system 10 may include a virtual measurement model 11. The virtual measurement model 11 may be configured to virtually measure a characteristic of a substrate processed by a specific process (e.g., etching process or deposition process) among various processes used in semiconductor device manufacturing. The substrate may be a target of the process, such as a wafer or base substrate.

The virtual measurement model 11 may include at least one model trained based on machine learning or deep learning. In one or more embodiments, the virtual measurement model 11 may include a first model 11-1 configured to extract a feature from input data and a second model 11-2 configured to generate virtual measurement data based on the extracted feature from the first model 11-1. When the input data is provided, the first model 11-1 may extract the feature of the input data. The feature of the input data extracted from the first model 11-1 may be inputted to the second model 11-2 to generate the virtual measurement data corresponding to the feature of the input data. The first model 11-1 may be trained to extract and output the feature of the input data when the input data is provided, and the second model 11-2 may be trained to generate and output the virtual measurement data when the feature of the input data is provided.

The input data may relate to a process for processing a substrate. The virtual measurement data may be data virtually measured based on the input data without requiring physical measurement and may be a prediction value indicating a characteristic (e.g., a process result) of the substrate. The characteristics of the substrate may include one or more physical characteristics such as height and width of a specific region of the substrate, such as an etched or deposited area. In one or more embodiments, the characteristic of the substrate may also be referred to as a processing state of the process on the substrate.

In one or more embodiments, the input data may be acquired during a manufacturing process. The process may be conducted under a consistent condition to meet a predetermined target value, and pieces of data acquired during the process may exhibit minimal variations (or change amounts). In other words, a slight difference may be present between pieces of input data, and the pieces of input data may have values similar to each other. In such cases, it may be difficult for the first model 11-1 to extract features. Traditional hand-crafted feature extraction techniques may require significant time and domain expertise, and may not scale effectively across complex manufacturing environments. The present disclosure provides one or more embodiments that enable improved accuracy in virtual measurement through training and inference using representative input data. Further detailed descriptions regarding one or more embodiments are provided below.

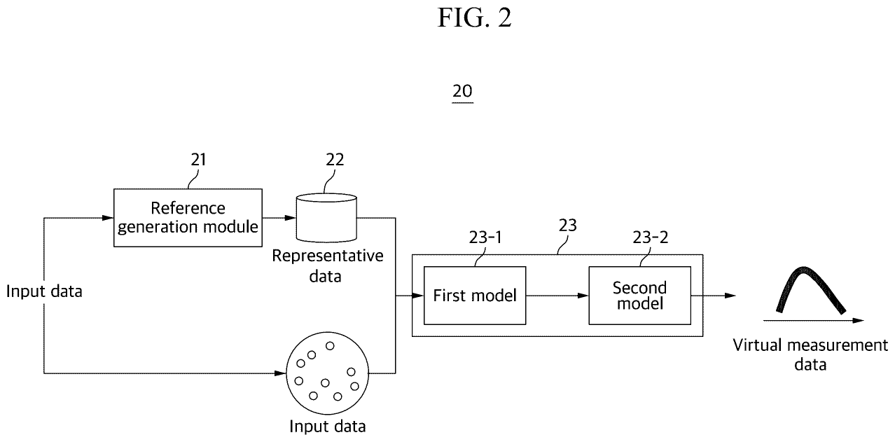

FIG. 2 illustrates a virtual measurement system according to one or more embodiments.

Referring to FIG. 2, a virtual measurement system 20 may virtually measure a characteristic of a substrate processed by a process based on input data and representative data. The description of the virtual measurement system 10 of FIG. 1 may be applied to the virtual measurement system 20 of FIG. 2, and a description overlapping with the above description is omitted.

The virtual measurement system 20 may include a reference generation module 21 and a virtual measurement model 23. The virtual measurement system 20 may further include a memory 22. In one or more embodiments, the reference generation module 21 may operate outside, separate from the virtual measurement model 23, or alternatively, may be modified and implemented as operating within the virtual measurement model 23. The virtual measurement model 23 may include a first model 23-1 and a second model 23-2. In one or more embodiments, each of the first model 23-1 and the second model 23-2 may be trained using a neural network model (for example, machine learning or deep learning). The examples of the model may include, but are not limited to, linear regression, logistic regression, a support vector machine (SVM), a decision tree, a random forest, k-nearest neighbors (k-NN), naive Bayes, an artificial neural network, a convolutional neural network (CNN), a recurrent neural network (RNN), long short-term memory (LSTM), a transformer-based model, a generative adversarial network (GAN), and an autoencoder. Each of the first model 23-1 and the second model 23-2 may include one or more layers, where a layer may comprise a computational unit for processing inputted data through a weight and an activation function and converting the data into an output, and a plurality of layers may be hierarchically connected. Operations (or computations) of the first model 23-1 and the second model 23-2 may be performed by an electronic device or one or more processors to be described below.

The reference generation module 21 may generate (or determine) at least one piece of representative data based on input data. In one or more embodiments, the reference generation module 21 may generate representative data representative of a distribution of the pieces of input data. The representative data may serve as a comparison criterion for quantitatively comparing a difference between input data and a data distribution. Depending on the characteristics of the input data, the number of the representative data may be determined to be one or plural. For example, when the distribution (or mode) of the input data is uni-modal, the number of the representative data may be one, and when the distribution (or mode) of the input data is multi-modal, the number of the representative data may be plural. The pieces of representative data generated from the reference generation module 21 may be stored in memory 22. In one or more embodiments, the reference generation module 21 may be implemented as a software module or a hardware module. For example, the software module may be implemented as a set of instructions executed by one or more processors, and the hardware module may be implemented as various forms such as a circuit confirmed to perform the above-described operations.

In one or more embodiments, the input data may include sensing data for the substrate being processed by the process and/or monitoring data of equipment performing the process. The sensing data may include optical emission spectroscopy (OES) data. For example, the OES data may be obtained by measuring light emitted from plasma in equipment performing a plasma etching process and may be used to identify a process state such as an etching end-point through change detection in gas and a secondary product (for example, a by-product). The monitoring data of the equipment may include fault detection classification (FDC) data and/or parameter data of the equipment. For example, the FDC data may be collected from the equipment or a sensor in real time and may be used to monitor a state of the equipment and/or fault detection.

In one or more embodiments, the reference generation module 21 may generate the representative data in different manners based on whether the process time is fixed or variable.

For fixed process durations, the reference generation module 21 may determine representative data by averaging the input data or selecting a medoid using Euclidean distance. Here, the averaging of the input data may be an arithmetic mean but may be modified to a manner using geometric mean or harmonic mean. The medoid may be a manner of calculating a sum of Euclidean distances between each input data and other data and determining input data of which the sum is minimum as the representative data. In such cases, when the length of time for processing the process is fixed, pieces of input data may correspond to, for example, time series data having the identical length of time.

For variable process durations, the reference generation module 21 may determine, based on a plurality of input data, representative data using barycenter averaging based on dynamic time warping (DTW). Here, the DTW may be an algorithm for non-linearly sorting pieces of input data having different lengths of time or distorted temporally to compare corresponding time points. The barycenter averaging may serve to compute an average of the corresponding time points for the pieces of input data sorted based on the DTW and determine the average as a value of a corresponding time point of the representative data. In such cases, when the length of time for processing the process varies, pieces of input data may correspond to, for example, time series data having lengths of time independent of each other.

In one or more embodiments, the reference generation module 21 may generate representative data for pieces of input data to which an identical criterion is applied/shared. Here, the representative data may be data representative of a group (or a set) of the pieces of input data to which the identical criterion is applied. In such cases, at least one piece of representative data may be determined/generated for each group. Here, the criterion may include equipment performing a process and/or a target value of the process. The criterion may be embedded in input data (or representative data) or managed as separate metadata. Here, the criterion may be referred to as an attribute.

The first model 23-1 may extract a feature of input data and a feature of representative data. For example, when the input data is provided, the first model 23-1 may extract the feature of the input data by performing a computation using the input data. When the representative data is inputted, the first model 23-1 may extract the feature of the representative data by performing a computation using the representative data. The input data and the representative data may be simultaneously inputted or sequentially inputted to the first model 23-1. The feature of the input data (or the representative data) may refer to specific information or patterns of the input data (or the representative data) and may be represented in the form of an n-dimensional vector (where n≥1). The input data and the representative data input to the first model 23-1 may be data in a corresponding relationship. For example, the input data and the representative data inputted to the first model 23-1 may be data to which an identical criterion is applied. This is to compare the input data and the representative data having the identical criterion to each other. Here, the first model 23-1 may be referred to as a feature extraction model or a preprocessing model. In such cases, a feature of data may be referred to as a characteristic.

When the feature of the input data and the feature of the representative data are extracted, the first model 23-1 may extract a final feature using a metric corresponding to a difference (or similarity) between the feature of the input data and the feature of the representative data. The metric may quantitatively compare the feature of the input data and the feature of the representative data and determine the difference or similarity between the features. Here, the metric may be information noise-contrastive estimation (InfoNCE) loss or Euclidean distance. For example, the InfoNCE loss may be defined as a loss function based on contrastive learning for comparing a similarity of a positive pair and a similarity of a negative pair to maximize the similarity of the positive pair and minimize the similarity of the negative pair. For example, the positive pair may be the feature of the input data and the feature of the representative data, and the negative pair may be the feature of the input data and a feature of another input data. The similarity between two features may be determined using a similarity function (for example, cosine similarity or inner product). For example, the Euclidean distance may be determined as a value obtained by taking a square root of a sum of squares of a difference by dimension between the feature of the input data and the feature of the representative data.

In one or more embodiments, a function of extracting the final feature using the metric may not be included in the first model 23-1 but in the second model 23-2 or may be implemented by a separate module between the first model 23-1 and the second model 23-2.

The second model 23-2 may generate virtual measurement data corresponding to the input data based on the feature of the input data and the feature of the representative data extracted from the first model 23-1. In such cases, when the final feature corresponding to the feature of the input data and the feature of the representative data is provided, the second model 23-2 may generate the virtual measurement data by performing a computation using the final feature. Specifically, when the feature of the input data and the feature of the representative data are provided, the second model 23-2 may determine the final feature using the metric corresponding to the difference (or similarity) between the feature of the input data and the feature of the representative data and generate the virtual measurement data by performing the computation using the final feature. Here, the second model 23-2 may be referred to as a regression model.

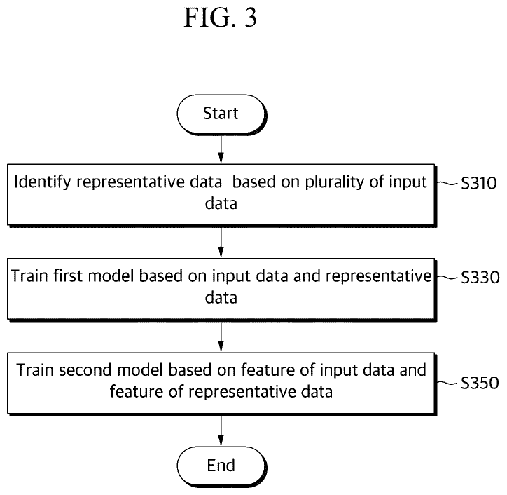

FIG. 3 illustrates a method of training a virtual measurement model according to one or more embodiments.

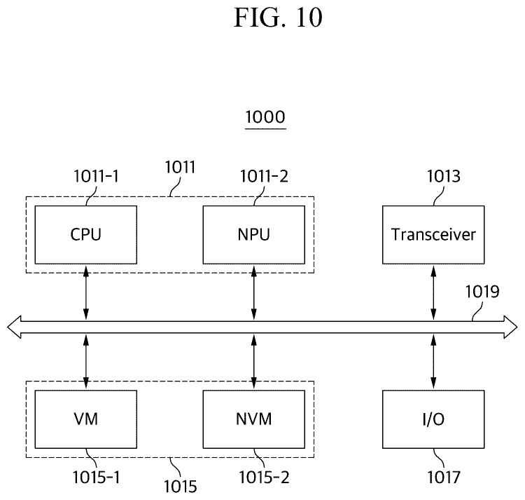

Referring to FIGS. 2 and 3, a method of training a virtual measurement model 23 of a substrate may include operations S310, S330, and S350. These operations may be performed by an electronic device or one or more processors, as described below with reference to FIG. 10. As an non-limiting example, operations S310, S330, and S350 may be performed by a graphics processing unit (GPU), neural processing unit (NPU), or other suitable processors. As used herein, “training” may refer to a series of processes for allowing a model to have higher accuracy or performance by optimizing internal parameters of the model using a set of training data. In one or more embodiments, a relationship between inputs and outputs of a model may be learned through various learning manners such as supervised learning, unsupervised learning, and contrastive learning.

In operation S310, at least one piece of representative data may be identified based on a plurality of input data. The plurality of input data may relate to a process of processing the substrate and serve as training data for training the virtual measurement model 23.

In one or more embodiments, the plurality of input data may include one or more of: sensing data obtained by measuring the substrate during the process; condition data of the process; and monitoring data of equipment performing the process. The sensing data may include OES data, image data, voltage data, and/or current data. The condition data of the process may include temperature inside the equipment, pressure, vacuum level, gas flow rate, gas velocity, humidity, and/or reaction time. The monitoring data of the equipment may include FDC data and/or parameter data. In such cases, preprocessing processes such as noise removal, normalization, and/or outlier removal may be performed on the plurality of input data.

For example, representative data may be determined based on the plurality of input data. When input data is selected for input to the first model 23-1, at least one piece of representative data corresponding to the selected input data may be identified. In one or more embodiments, a criterion may be applied to each of the plurality of input data. At least one piece of representative data may be determined for pieces of input data to which an identical criterion is applied among the plurality of input data. Techniques such as averaging, medoid calculation using Euclidean distance, or barycenter averaging using dynamic time warping (DTW) may be used to determine representative data. Redundant descriptions are omitted here for clarity.

In operation S330, the first model 23-1 may be trained using the input data and the at least one piece of representative data. For example, operation S330 may include a training process of gradually updating internal parameters of the first model 23-1 based on the input data and the at least one piece of representative data.

In one or more embodiments, the input data and the at least one piece of representative data may be provided to the first model 23-1, and the first model 23-1 may perform a computation for each of the input data and the at least one piece of representative data using internal parameters of a current state. The first model 23-1 may extract a feature of the input data and a feature of the at least one piece of representative data as a computation result. In such cases, a first loss function for evaluating the computation result of the first model 23-1 may be used for training the first model 23-1. A value of the first loss function may quantitatively represent an error of the first model 23-1, and based on the value of the first loss function, the internal parameters of the first model 23-1 may be updated through optimization techniques such as a backpropagation algorithm and gradient descent. By repeating this update process, the parameters of the first model 23-1 may be gradually updated so that the first model 23-1 may improve its ability to extract meaningful features from the input and representative data.

In operation S350, the second model 23-2 may be trained based on the feature of the input data and the feature of the at least one piece of representative data, which are extracted by the first model 23-1. For example, operation S350 may include a training process of gradually updating internal parameters of the second model 23-2 based on the feature of the input data and the feature of the representative data. The second model 23-2 may generate virtual measurement data corresponding to the input data based on the feature of the input data and the feature of the representative data. The description of the first model 23-1 may be identically applied to training the second model 23-2. For example, a second loss function for evaluating a computation result of the second model 23-2 may be used for training the second model 23-2. A value of the second loss function may quantitatively represent an error between the virtual measurement data generated by the second model 23-2 and measurement data, and based on the value of the second loss function, the internal parameters of the second model 23-2 may be updated through optimization techniques such as a backpropagation algorithm and gradient descent.

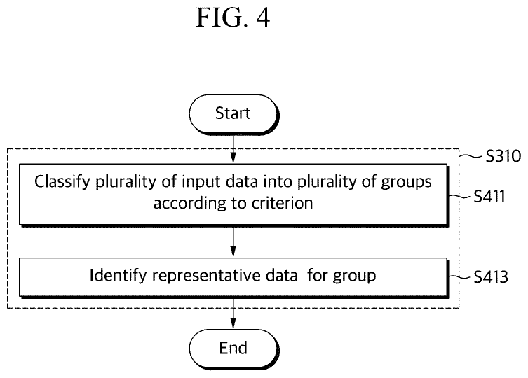

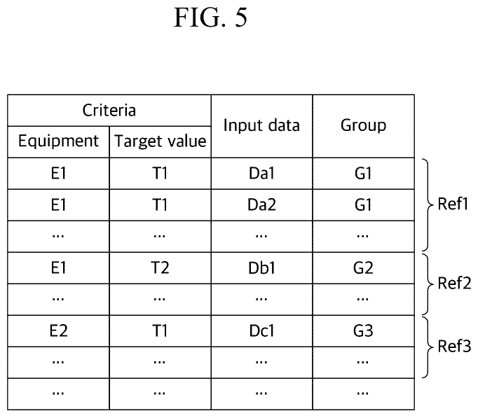

FIG. 4 illustrates a method of training a virtual measurement model according to one or more embodiments. FIG. 5 illustrates a relationship between input data and representative data according to one or more embodiments.

Referring to FIGS. 2 and 4, a method of training a virtual measurement model of a substrate may include operations S411 and S413. Operations S411 and S413 may be included in operation S310 of FIG. 3 and may be performed by the reference generation module 21 of FIG. 2.

In operation S411, a plurality of input data may be classified into a plurality of groups based on a process-related criterion. Such criterion may include equipment performing the process and/or a target value of the process. A specific criterion may be associated with each of the plurality of input data. For example, input data may be obtained from the equipment performing the process. The plurality of input data may be obtained during the process under a condition for satisfying the target value (for example, target specifications) of the process.

In operation S413, at least one piece of representative data is identified for each group of input data sharing an identical criterion. In such cases, at least one piece of representative data may be predetermined for each group and used as input to the first model 23-1 along with the corresponding input data.

For example, referring to FIGS. 4 and 5, the plurality of input data may include first input data Da1, second input data Da2, third input data Db1, and fourth input data Dc1. The input data may be grouped into a first group G1, a second group G2, and a third group G3. The first input data Da1, the second input data Da2, and the third input data Db1 may be obtained from first equipment E1, and the fourth input data Dc1 may be obtained from second equipment E2. Here, the first equipment E1 and the second equipment E2 may be an identical type of equipment or different types of equipment. The first input data Da1, the second input data Da2, and the fourth input data Dc1 may be obtained under a condition meeting a first target value T1, and the third input data Db1 may be obtained under a condition meeting a second target value T2.

In such cases, pieces of input data, such as the first input data Da1 and the second input data Da2, to which the first equipment E1 and the first target value T1 are applied may be classified into the first group G1. Pieces of input data, such as the third input data Db1, to which the first equipment E1 and the second target value T2 are applied may be classified into the second group G2. Pieces of input data, such as the fourth input data Dc1, to which the second equipment E2 and the first target value T1 are applied may be classified into the third group G3.

Based on the pieces of input data, such as the first input data Da1 and the second input data Da2, classified into the first group G1, first representative data Ref1 may be determined for the first group G1. Based on the pieces of input data, such as the third input data Db1, classified into the second group G2, second representative data Ref2 may be determined for the second group G2. Based on the pieces of input data, such as the fourth input data Dc1, classified into the third group G3, third representative data Ref3 may be determined for the third group G3. In other words, at least one piece of representative data may be determined for pieces of input data to which an identical criterion is applied among the plurality of input data. Various techniques such as an average or a medoid based on Euclidean distance and barycenter averaging based on DTW may be applied to determine the representative data.

In one or more embodiments, operation S413 may include, when the length of time for processing a process corresponding to the input data is fixed, identifying at least one piece of representative data determined using an average or a medoid based on Euclidean distance among a plurality of input data included in the group to which the identical criterion applied to the input data is applied. Operation S413 may include, when the length of time for processing a process corresponding to the input data varies, identifying at least one piece of representative data determined using barycenter averaging based on DTW among a plurality of input data included in the group to which the identical criterion applied to the input data is applied.

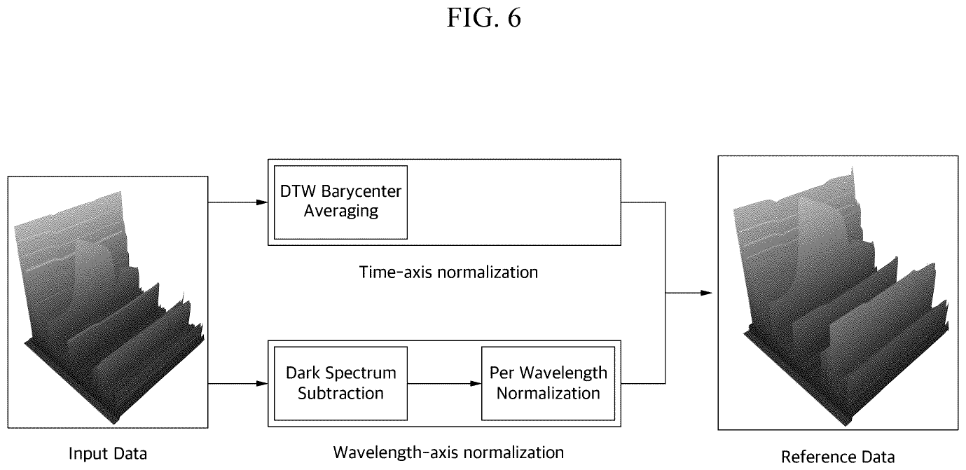

FIG. 6 illustrates a process of generating representative data by processing input data according to one or more embodiments.

Referring to FIG. 6, representative data may be generated after performing normalization on pieces of input data. The pieces of input data and the representative data may include, for example, OES data. The operations shown in FIG. 6 may be performed by the reference generation module 21 of FIG. 2.

The OES data may be two-dimensional data representing intensity (or strength) for both a wavelength axis and a time axis. When input data is the OES data, representative data may be generated by considering both the wavelength axis and the time axis. For example, a unit of intensity may be an arbitrary unit, and without performing calibration, differences in intensity values may arise depending on equipment.

For OES data measured in each equipment, calibration may be performed using a respective dark spectrum of each equipment. A dark spectrum may be present in equipment and may represent a background noise of a measurement environment and/or an offset other than light emitted from plasma. Upon completing calibration, the normalization (or scaling processing) per wavelength may be performed on the OES data. The normalization may convert a value of data into a standardized size to facilitate comparison.

Since a measurement time of the OES data measured in each equipment may be different for each equipment, barycenter averaging based on DTW may be used. This averaging technique enables alignment of OES data with varying time lengths and allows for the generation of representative data based on the aligned datasets. By generating representative data that considers both the wavelength and time axes, more accurate comparison and analysis of the entire set of OES data may be achieved.

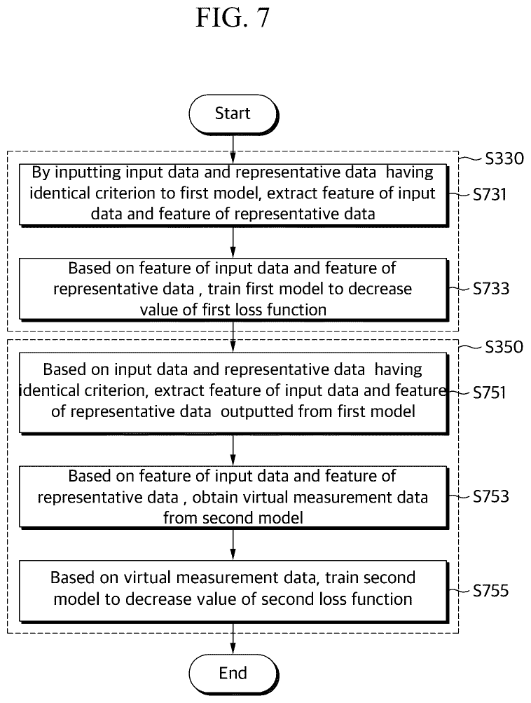

FIG. 7 illustrates a method of training a virtual measurement model according to one or more embodiments.

Referring to FIGS. 2 and 7, a method of training a virtual measurement model of a substrate may include operations S731, S733, S751, S753, and S755. Operations S731 and S733 of FIG. 7 may be included in operation S330 of FIG. 3. Operations S751, S753, and S755 of FIG. 7 may be included in operation S350 of FIG. 3.

In operation S731, input data and at least one piece of representative data having an identical criterion are input to the first model 23-1 to extract a feature of the input data and a feature of the at least one piece of representative data. The input data and the at least one piece of representative data may be simultaneously or sequentially provided to the first model 23-1. The input data and the at least one piece of representative data may be data to which the identical criterion is applied. For example, the input data may include OES data. However, this is an example, and a type of data included in the input data may be modified and other substrate-process-related data types may alternatively be used.

In operation S733, based on the extracted features from the input data and the at least one piece of representative data, the first model 23-1 may be trained to decrease a value of a first loss function. For example, by inputting the feature of the input data and the feature of the at least one piece of representative data extracted by the first model 23-1 as a variable of the first loss function and computing the first loss function, the value of the first loss function may be obtained. In addition, by repeatedly performing a series of processes of updating internal parameters of the first model 23-1 to decrease the value of the first loss function, the first model 23-1 may be trained.

In one or more embodiments, the first loss function may include one or more of a metric, a hyperparameter, and a similarity between first measurement data and second measurement data. The metric may be a function corresponding to a difference between the feature of the input data and the feature of the at least one piece of representative data. The hyperparameter may be a parameter corresponding to sharpness. The first measurement data may correspond to the input data, and the second measurement data may correspond to the at least one piece of representative data. The input data may be obtained during a process, and the first measurement data corresponding to the input data may be obtained through physical measurement for a substrate after the process is processed. The representative data may be obtained during a process, and the second measurement data corresponding to the representative data may be obtained through physical measurement for a substrate after the process is processed. If the representative data is obtained through a computation and input data identical to the representative data is not present, the second measurement data corresponding to the representative data may be obtained as a value estimated using a separate model (for example, a mapping function or a regression model).

In one or more embodiments, the first loss function may be defined as a function described in Equation 1 below. This is an example, and the first loss function may be defined as other various forms of functions.

$$Loss 1 = 2 α \cdot σ ( - τ \cdot D ( {f}_{θ} ( x ) , {f}_{θ} ( r ) ) ) \qquad Equation 1$$

Here, Loss1 may be a first loss function, x may be input data for a substrate, r may be representative data corresponding to the input data, and f_{θ} may be an extraction function included in the first model 23-1 for extracting a feature of the input data and a feature of the representative data. D is a metric indicating Euclidean distance on a feature space. τ is a hyperparameter for controlling sharpness, and a is a similarity between a target value corresponding to the input data and a target value corresponding to the representative data. In such cases, f_{θ}(x) may be the feature of the input data, and f_{θ}(r) may be the feature of the representative data. Accordingly, D(f_{θ}(x), f_{θ}(r)) may be referred to as a final feature described above.

In operation S751, based on the input data and the at least one piece of representative data having the identical criterion, the feature of the input data and the feature of the at least one piece of representative data may be extracted using the first model 23-1. Here, the first model 23-1 may be in a state in which training has been completed.

In operation S753, based on the extracted feature of the input data and the extracted feature of the at least one piece of representative data having the identical criterion, virtual measurement data may be generated using the second model 23-2.

In operation S755, based on the virtual measurement data, the second model 23-2 may be trained to decrease a value of a second loss function. For example, by inputting the virtual measurement data generated from the second model 23-2 as a variable of the second loss function and computing the second loss function, the value of the second loss function may be obtained. In addition, by repeatedly performing a series of processes of updating internal parameters of the second model 23-2 to decrease the value of the second loss function, the second model 23-2 may be trained.

In one or more embodiments, the second loss function may include the virtual measurement data corresponding to the input data and a difference between the first measurement data corresponding to the input data and the second measurement data corresponding to the at least one piece of representative data. In such embodiments, the virtual measurement data may correspond to an output value generated by the second model 23-2.

In one or more embodiments, the second loss function may be defined as a function represented by Equation 2 below. However, this is merely an example, and the second loss function may be defined in other various forms.

$$Loss 2 = {‖ {g}_{ϕ} ( D ( {f}_{θ} ( x ) , {f}_{θ} ( r ) ) ) - ( y - \overline{y} ) ‖}^{2} \qquad Equation 2$$

Here, Loss2 may be a second loss function, x may be input data for a substrate, r may be representative data corresponding to the input data, and f_{θ} may be a function of the first model 23-1 for extracting a feature of the input data and a feature of the representative data. D is a metric indicating Euclidean distance on a feature space. g_{φ} may be a virtual measurement function included in the second model 23-2 for calculating virtual measurement data corresponding to the input data. y is a target value corresponding to the input data, and y is a target value corresponding to the representative data.

In one or more embodiments, the first model 23-1 and the second model 23-2 are described as being implemented as separate models. However, implementing the two models as a single integrated model is also within the scope of the present disclosure.

According to one or more embodiments, after obtaining representative data paired with input data from the input data and extracting features of both the input data and the representative data using the first model 23-1, virtual measurement data may be generated by inputting the extracted features into the second model 23-2. This approach may improve accuracy compared to a method that inputs only a single piece of input data to extract a corresponding feature and subsequently obtain virtual measurement data through a regression model.

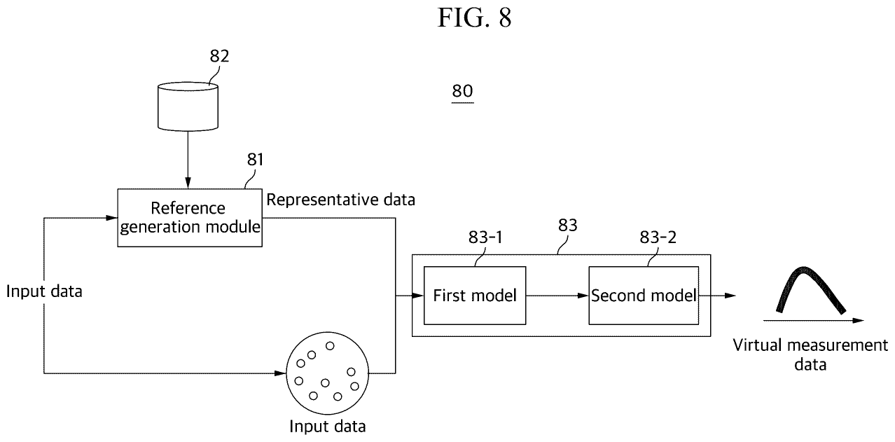

FIG. 8 illustrates a virtual measurement system according to one or more embodiments.

Referring to FIG. 8, a virtual measurement system 80 may virtually measure a characteristic of a substrate processed by a given process, based on input data and representative data. The descriptions of the virtual measurement systems 10 and 20 of FIGS. 1 and 2, respectively, may apply to the virtual measurement system 80 of FIG. 8. Accordingly, overlapping descriptions are omitted for brevity.

In one or more embodiments, the virtual measurement system 80 may include a reference generation module 81, a virtual measurement model 83, and a memory 82.

The reference generation module 81 may reside outside the virtual measurement model 83. However, this is merely illustrative, and the reference generation module 81 may alternatively be integrated with the virtual measurement model 83. The virtual measurement model 83 may include a first model 83-1 and a second model 83-2, each of which may be a model trained based on machine learning or deep learning. The memory 82 may store representative data. The memory 82 may correspond to a memory described below in FIG. 10. For reference, the memory 82 may store the virtual measurement model 83, including the first model 83-1 and the second model 83-2, along with the representative data.

According to one or more embodiments, the virtual measurement system 80 may perform accurate prediction for input data that exhibits minor variations by using representative data associated with the input data. In other words, without relying on physical measurements using instruments such as a scanning electron microscope (SEM) or an atomic force microscope (AFM) for a substrate processed by a process (or a substrate for which a process is finished), the virtual measurement system 80 may accurately predict/estimate a characteristic of the substrate based on input data. Accordingly, the virtual measurement system 80 may support real-time monitoring of multiple substrates, reduce production delays associated with measurement time, and lower measurement costs, thereby improving overall productivity.

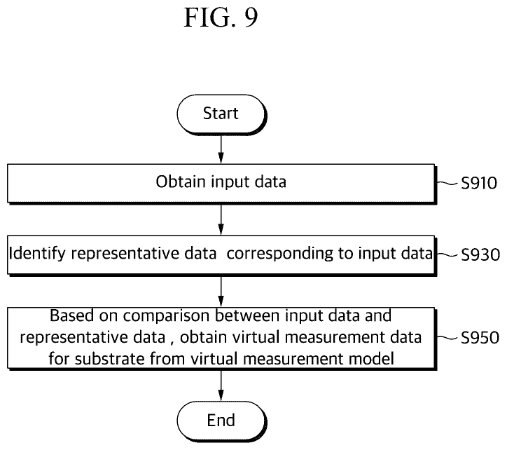

FIG. 9 illustrates a method of virtual measurement of a substrate according to one or more embodiments.

Referring to FIGS. 8 and 9, a method of virtual measurement of a substrate may include operations S910, S930, and S950. These operations may be performed by an electronic device or one or more processors, as described in further detail below with reference to FIG. 10.

In operation S910, input data related to a substrate processing operation may be obtained. For example, the input data may be collected from the processing equipment and provided to the reference generation module 81.

In operation S930, at least one piece of representative data corresponding to the input data may be identified. The reference generation module 81 may identify and retrieve the at least one piece of representative data associated with the input data from the memory 82. For reference, the at least one piece of representative data may be stored in the memory 82 in advance. Among a plurality of representative data having different criteria, the representative data having a criterion identical to that of the input data may be determined/selected. Here, the criterion may include equipment performing the process and/or a target value of the process. For example, the reference generation module 81 may identify and fetch representative data having a criterion identical to the criterion of the input data from the memory 82. The reference generation module 81 may transfer both the input data and the identified representative data to the virtual measurement model 83. In such cases, the reference generation module 81 may be referred to as a reference fetch module.

In operation S950, based on a comparison between the input data and the at least one piece of representative data, virtual measurement data for the substrate may be generated by the virtual measurement model 83.

Here, the virtual measurement model 83 may include the first model 83-1 and the second model 83-2. The first model 83-1 may extract a feature of the input data and a feature of the at least one piece of representative data, and the second model 83-2 may generate the virtual measurement data corresponding to the input data based on the extracted features output from the first model 83-1. For example, the input data and the at least one piece of representative data may be provided to the first model 83-1 to extract the feature of the input data and the feature of the at least one piece of representative data. The respective extracted features may then be provided to the second model 83-2 to generate the virtual measurement data corresponding to the input data. In an example embodiment, the first model 83-1 and the second model 83-2 may be implemented as a single, integrated model.

In such cases, the first model 83-1 may be trained to extract the feature of the input data and the feature of the at least one piece of representative data. Based on the extracted respective features of the input data and the at least one piece of representative data, the first model 83-1 may be trained to decrease a value of a first loss function.

The second model 83-2 may be trained to generate the virtual measurement data based on the feature of the input data and the feature of the at least one piece of representative data. The second model 83-2 may be trained to decrease a value of a second loss function including the virtual measurement data and a difference between first measurement data corresponding to the input data and second measurement data corresponding to the at least one piece of representative data. Further details on training are omitted due to redundancy with previously described embodiments.

Furthermore, the second model 83-2 may generate the virtual measurement data for the substrate based on a final feature indicating a result of comparing the feature of the input data and the feature of the at least one piece of representative data. The final feature may be derived using a metric corresponding to a difference between the feature of the input data and the feature of the at least one piece of representative data.

For example, the first model 83-1 may be configured to extract the feature of the input data and the feature of the at least one piece of representative data and generate the final feature based on the feature of the input data and the feature of the at least one piece of representative data. The final feature may be transferred from the first model 83-1 to the second model 83-2. As another example, the first model 83-1 may be configured to extract and output the feature of the input data and the feature of the at least one piece of representative data. The final feature may be generated based on the feature of the input data and the feature of the at least one piece of representative data and transferred to the second model 83-2 by a metric module disposed between the first model 83-1 and the second model 83-2.

FIG. 10 illustrates an electronic device according to one or more embodiments.

Referring to FIGS. 8 and 10, an electronic device 1000 may be implemented as a computer or server managing one or more pieces of processing equipment. This is illustrative only, and the electronic device 1000 may be modified and implemented as various types of electronic devices such as a smartphone, a tablet personal computer (PC), and a wearable device.

The electronic device 1000 may include one or more processor 1011, a transceiver 1013, a memory 1015, and an input/output part (“I/O”) 1017, all connected via a bus 1019.

The one or more processors 1011 may include a first processor and a second processor. The first processor may include a central processing unit (CPU) 1011-1 as an example, and the second processor may include a neural processing unit (NPU) 1011-2 as an example. This is merely an example embodiment, and the first processor may be implemented as other forms such as an application processor (AP), a digital signal processor (DSP), and a microcontroller unit (MCU) or may further include another type of processor. The second processor may be implemented as other forms such as a graphics processing unit (GPU), a tensor processing unit (TPU), and an artificial intelligence (AI) accelerator or may further include another type of processor.

The transceiver 1013 may transmit and receive data to and from an external device. For example, the external device may be equipment performing a process of processing a substrate. In example embodiments, the transceiver 1013 may receive input data related to the process from the equipment. In one or more embodiments, the transceiver 1013 may transmit alarm information to the equipment based on virtual measurement data. The transceiver 1013 may support various communication manners to communicate with the external device through a wired or wireless communication manner. For example, the transceiver 1013 may perform wired communication through a manner of Ethernet communication or serial communication such as Recommended Standard 232 (RS-232), RS-485, Modbus, Open Platform Communications Unified Architecture (OPC UA), and Profinet. As another example, the transceiver 1013 may perform wireless communication through communication manners such as Wi-Fi, Bluetooth, and ZigBee.

The memory 1015 may store data. In example embodiments, the memory 1015 may store pieces of representative data classified according to a criterion. In one or more embodiments, the memory 1015 may store the virtual measurement model 83 trained to output virtual measurement data based on a comparison between input data and at least one piece of representative data. Alternatively, the memory 1015 may store at least a portion of the virtual measurement model 83. For example, the memory 1015 may store at least one of the first model 83-1 and the second model 83-2 of the virtual measurement model 83. In one or more embodiments, the reference generation module 81 may be implemented as a software module. In such cases, the memory 1015 may store the reference generation module 81.

In example embodiments, the memory 1015 may include volatile memory (VM) 1015-1 and non-volatile memory (NVM) 1015-2. The VM 1015-1 may store data while power is supplied only. The VM 1015-1 may allow data reading and writing at a relatively high speed and thus may be used for storing temporary data or cache data in an operation requiring high speed processing. For example, the VM 1015-1 may be implemented as dynamic random access memory (DRAM) or static random access memory (SRAM). The NVM 1015-2 may maintain stored data even when power is disconnected. For example, the NVM 1015-2 may be implemented as NAND flash memory, NOR flash memory, electrically erasable programmable read-only memory (EEPROM), ferroelectric RAM (FeRAM), magnetoresistive RAM (MRAM), or resistive RAM (ReRAM).

The input/output part 1017 may include one or more of various input devices and output devices that enable interactions between the electronic device 1000 and a user. For example, the input device may be implemented as a keyboard that senses a key input of the user, a mouse that senses a point input of the user, or a touch panel that senses a touch input of the user. For example, the output device may be implemented as a display that outputs video information such as image and text or a speaker that outputs sound information such as voice and alarm.

The first processor may control overall operations of the electronic device 1000. The first processor may process general-purpose data or perform an operation such as arithmetic logic. The first processor may allocate or manage a resource of the electronic device 1000 by executing an operating system or firmware. The second processor may perform an operation related to training and inference of the virtual measurement model 83. In other words, the first processor may be interlinked with the second processor to perform some operations related to the virtual measurement model 83. The number of the processor 1011 is illustrated as plural, but the number of the processor 1011 may be modified and implemented as one. In this case, the processor 1011 may be implemented, for example, as a form of a system on chip (SoC).

The first processor may identify at least one piece of representative data to which an identical criterion applied to input data is applied in the memory 1015. For example, if the input data is received, the first processor may identify the representative data having the identical criterion in the memory 1015. In addition, the first processor may transfer the input data and the representative data to the second processor.

The second processor may obtain virtual measurement data for a substrate based on a comparison between the input data and the at least one piece of representative data. In other words, the second processor may obtain the virtual measurement data for the substrate using the virtual measurement model 83 based on the comparison between the input data and the at least one piece of representative data. For example, if the input data and the representative data are received from the first processor, the second processor may input the input data and the representative data to the first model 83-1 of the virtual measurement model 83 and perform an operation to extract a feature of the input data and a feature of the representative data. The second processor may input each feature or a final feature to the second model 83-2 and perform an operation to obtain the virtual measurement data for the substrate. The second processor may transfer the virtual measurement data to the first processor.

In one or more embodiments, the virtual measurement data may be compared with a threshold range that is a criterion for outputting alarm information regarding the substrate. For example, the first processor may receive the virtual measurement data generated in the second processor. The first processor may compare a value of the virtual measurement data and a preset threshold range to determine whether to output alarm information depending on a comparison result. For example, the first processor may determine not to output the alarm information when the value of the virtual measurement data falls within the threshold range and determine to output the alarm information when the value of the virtual measurement data falls outside the threshold range. The first processor may output the alarm information when the value of the virtual measurement data falls outside the threshold range. For example, the first processor may output the alarm information via the input/output part 1017. As another example, the first processor may output the alarm information to an external device (for example, equipment of a corresponding process) via the transceiver 1013.

The computing apparatuses, the electronic devices, the processors, the memories, the transceivers, the I/O devices and other apparatuses, devices, units, and components described herein with respect to FIGS. 1-10 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-10 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software include higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as a multimedia card or a micro card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.
While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure

What is claimed is:

1. A processor-implemented method of training a virtual measurement model of a substrate, the virtual measurement model comprising a first model and a second model, the method comprising:
identifying at least one piece of representative data determined based on a plurality of input data associated with a process of processing the substrate;
training the first model, based on the input data and the at least one piece of representative data, to extract and output a feature of the input data and a feature of the at least one piece of representative data; and
training the second model, based on the features output from the first model, to generate virtual measurement data corresponding to the input data.

2. The method of claim 1, wherein the identifying of the at least one piece of representative data comprises:
classifying the plurality of input data into a plurality of groups based on a criterion related to the process; and
identifying at least one piece of representative data determined for a group to which a criterion identical to a criterion of the input data is applied among the plurality of groups.

3. The method of claim 2, wherein the criterion includes either one or both of equipment performing the process and a target value of the process.

4. The method of claim 2, wherein the identifying of the at least one piece of representative data comprises:
in response to a fixed processing time for a process corresponding to the input data,
identifying the at least one piece of representative data based on an average or a medoid using Euclidean distance among the input data included in the group to which the identical criterion applied to the input data is applied.

5. The method of claim 2, wherein the identifying of the at least one piece of representative data comprises:
in response to a variable processing time for a process corresponding to the input data,
identifying the at least one piece of representative data based on barycenter averaging using dynamic time warping among the input data included in the group to which the identical criterion applied to the input data is applied.

6. The method of claim 2, wherein the training of the first model comprises:
inputting the input data and the at least one piece of representative data, having the identical criterion, into the first model, to extract a feature of the input data and a feature of the at least one piece of representative data; and
training the first model to decrease a value of a first loss function based on the feature of the input data and the feature of the at least one piece of representative data.

7. The method of claim 6, wherein the first loss function includes:
a metric corresponding to a difference between the feature of the input data and the feature of the at least one piece of representative data;
a hyperparameter corresponding to sharpness; and
a similarity between first measurement data corresponding to the input data and second measurement data corresponding to the at least one piece of representative data.

8. The method of claim 2, wherein the training of the second model comprises:
extracting the feature of the input data and the feature of the at least one piece of representative data using the first model;
generating the virtual measurement data using the second model based on the extracted features; and
training the second model to decrease a value of a second loss function based on the generated virtual measurement data.

9. The method of claim 8, wherein the second loss function includes the virtual measurement data and a difference between first measurement data corresponding to the input data and second measurement data corresponding to the at least one piece of representative data.

10. The method of claim 1, wherein the plurality of input data comprises one or more of:
sensing data obtained by measuring the substrate during the process;
condition data of the process; and
monitoring data of equipment performing the process.

11. A processor-implemented method of virtual measurement of a substrate, the method comprising:
obtaining input data associated with a process of processing the substrate;
identifying at least one piece of representative data corresponding to the input data; and
based on a comparison between the input data and the at least one piece of representative data, generating virtual measurement data for the substrate using a virtual measurement model.

12. The method of claim 11, wherein the identifying of the at least one piece of representative data comprises selecting, from among a plurality of representative data stored in a memory, the at least one piece of representative data having a criteria identical to a criterion of the input data.

13. The method of claim 12, wherein the criterion includes either one or both of equipment performing the process and a target value of the process.

14. The method of claim 11, wherein the virtual measurement model comprises:
a first model configured to extract a feature of the input data and a feature of the at least one piece of representative data; and
a second model configured to generate virtual measurement data corresponding to the input data based on the extracted features outputted by the first model.

15. The method of claim 14, wherein the first model is trained to decrease a value of a first loss function based on the feature of the input data and the feature of the at least one piece of representative data.

16. The method of claim 14, wherein the second model is trained to generate the virtual measurement data and decrease a value of a second loss function including the virtual measurement data and a difference between first measurement data corresponding to the input data and second measurement data corresponding to the at least one piece of representative data.

17. The method of claim 14, wherein the second model generates the virtual measurement data for the substrate based on a final feature indicating a difference between the feature of the input data and the feature of the at least one piece of representative data is inputted, and
wherein the final feature is determined using a metric corresponding to the difference.

18. An electronic device comprising:
a memory;
a transceiver configured to receive input data related to a process of processing a substrate from processing equipment;
a first processor configured to identify, from the memory, at least one piece of representative data having a criterion identical to that of the input data and to output the input data and the at least one piece of representative data; and
a second processor configured to generate virtual measurement data for the substrate based on a comparison between the input data and the at least one piece of representative data.

19. The electronic device of claim 18, wherein the virtual measurement data is compared with a threshold range, and an alarm is triggered when the virtual measurement data falls outside the threshold range.

20. The electronic device of claim 18, wherein the memory stores a virtual measurement model trained to output the virtual measurement data based on the comparison between the input data and the at least one piece of representative data.
